(19) United States
(12) Patent Application Publication
(10) Pub. No.: US 2010/0114513 A1
(43) Pub. Date: May 6, 2010

(54) ESTIMATING MINIMUM VOLTAGE OF FUEL CELLS

(75) Inventors: Kiran Mallavarapu, Honeoye Falls, NY (US); Sanja Sljivar-Lovria, Honeoye Falls, NY (US); Balasubramanian Lakshmanan, Pittsford, NY (US); Michael F. Zawisa, Victor, NY (US)

Correspondence Address: General Motors Corporation;c/o REISING, ETHINGTON, BARNES, KISSELLE, P.C., P.O. BOX 4390, TROY, MI, 48099-4390, US

(73) Assignee: GM GLOBAL TECHNOLOGY OPERATIONS, INC., Detroit, MI (US)

(21) Appl. No.: 12/262,592

(22) Filed: Oct. 31, 2008

(51) Int. Cl. G01R 19/00

(52) U.S. Cl. 702/64

(57) ABSTRACT

A method of estimating minimum voltage of fuel cells, and a product using same.

### TECHNICAL FIELD

The field to which the disclosure generally relates includes fuel cells and related methods of operation.

### BACKGROUND

Fuel cells are electrochemical energy conversion devices that use inputs of hydrogen and oxygen in a catalyzed reaction to produce a byproduct of water and a useful output of electricity. Individual fuel cells are usually electrically connected in series to form a stack. For example, a stack of 200 fuel cells, each of which may produce about 0.75 volts, may output about 150 volts. Stack voltage is monitored to ensure good stack operation, and individual cell voltages may be monitored to assess low voltage conditions that may trigger reduced operation or even shutdown of the stack or an entire fuel cell system including the stack.

But directly measuring the voltage of each and every individual fuel cell can be complex and cost prohibitive. To minimize the voltage measurements, adjacent fuel cells are often clustered into groups and a voltage of each group is monitored and minimum cell voltages are estimated via the groups. But typical minimum voltage estimation methods assume that there is only one minimally performing cell in each group and that the other cells in each group are at an average cell voltage of the entire stack.

### SUMMARY OF EXEMPLARY EMBODIMENTS

One exemplary embodiment may include a method including:

measuring stack voltage of a fuel cell stack;

calculating average cell voltage (ν_{C,ave}) for the stack;

measuring group voltages of a plurality of groups of fuel cells of the stack;

identifying a group of the plurality of groups having a minimum group voltage (ν_{G,min}), which is lower than the measured group voltages of a remainder of the plurality of groups;

calculating a group voltage deviation (Y) for the identified group by multiplying the quantity of fuel cells (N_{M}) of the identified group by the calculated average cell voltage and then subtracting the measured group voltage of the identified group; and

estimating a minimum cell voltage (ν_{GC,min}) of the identified group according to a function wherein:
if Y is less than or equal to a value, then ν_{GC,min} equals ν_{G,min} minus (N_{M}−1)*(ν_{C,ave}); and
if Y is greater than the value, then ν_{GC,min} equals at least one of ν_{G,min} multiplied by a constant or ν_{G,min} plus a variable.

Another exemplary embodiment may include a method including a) identifying a group of a plurality of groups of fuel cells of a fuel cell stack having a minimum group voltage (ν_{G,min}), which is lower than any group voltage of a remainder of the plurality of groups; b) calculating a group voltage deviation (Y) for the identified group by multiplying the quantity of fuel cells (N_{M}) of the identified group by an average cell voltage (ν_{C,ave}) of the fuel cell stack and then subtracting the minimum group voltage; and c) estimating a minimum cell voltage (ν_{GC,min}) of the identified group according to a function including a step wherein if Y is less than or equal to a value, then ν_{GC,min} equals ν_{G,min} minus (N_{M}−1)*(ν_{C,ave}).

A further exemplary embodiment may include a product, which includes a fuel cell stack including a plurality of fuel cells, at least some of which are clustered into a plurality of groups. The product may also include a voltage monitoring device coupled to the fuel cell stack to measure stack voltage of the fuel cell stack and group voltages of at least some of the plurality of groups. The product may further include a controller coupled to the voltage monitoring device to:
calculate average cell voltage (ν_{C,ave}) for the stack,
identify a group of the plurality of groups having a minimum group voltage (ν_{G,min}), which is lower than the measured group voltages of a remainder of the plurality of groups,
calculate a group voltage deviation (Y) for the identified group by multiplying the quantity of fuel cells (N_{M}) of the identified group by the calculated average cell voltage and then subtracting the measured group voltage of the identified group, and
estimate a minimum cell voltage (ν_{GC,min}) of the identified group according to a function wherein:
   if Y is less than or equal to a value, then ν_{GC,min} equals ν_{G,min} minus (N_{M}−1)*(ν_{C,ave}); and
   if Y is greater than the value, then ν_{GC,min} equals at least one of ν_{G,min} multiplied by a constant or ν_{G,min} plus a variable.

An additional exemplary embodiment may include a product, which includes a means for identifying a group of a plurality of groups of fuel cells of a fuel cell stack having a minimum group voltage (ν_{G,min}), which is lower than any group voltage of a remainder of the plurality of groups. The product also includes a means for calculating a group voltage deviation (Y) for the identified group by multiplying the quantity of fuel cells (N_{M}) of the identified group by an average cell voltage (ν_{C,ave}) of the fuel cell stack and then subtracting the minimum group voltage. The product further includes a means for estimating a minimum cell voltage (ν_{GC,min}) of the identified group according to a function including a step wherein if Y is less than or equal to a value, then ν_{GC,min} equals ν_{G,min} minus (N_{M}−1)*(ν_{C,ave}).

Other exemplary embodiments will become apparent from the detailed description provided hereinafter. It should be understood that the detailed description and specific examples, while disclosing exemplary embodiments, are intended for purposes of illustration only and are not intended to limit the scope of the claims.

### BRIEF DESCRIPTION OF THE DRAWINGS

Exemplary embodiments will become more fully understood from the detailed description and the accompanying drawings, wherein:

FIG. 1 is schematic view of an exemplary embodiment of a fuel cell system including a fuel cell stack of individual fuel cells;

FIG. 2 is a partial schematic view of an exemplary embodiment of a fuel cell of the fuel cell stack of FIG. 1;

FIG. 3 is a flow chart of an exemplary embodiment of a method of estimating minimum voltage of fuel cells;

FIG. 4 is a table of results of a prior art technique in comparison to results of the exemplary embodiment of FIG. 3;

FIG. 5 is a prior art histogram of error of minimum voltage estimates as a result of using a conventional voltage estimation technique; and

FIG. 6 is an illustrative histogram of error of minimum voltage estimates as a result of using the exemplary method of FIG. 3.

### DETAILED DESCRIPTION OF EXEMPLARY EMBODIMENTS

The following description of the exemplary embodiment(s) is merely illustrative in nature and is in no way intended to limit the claims, their application, or uses.

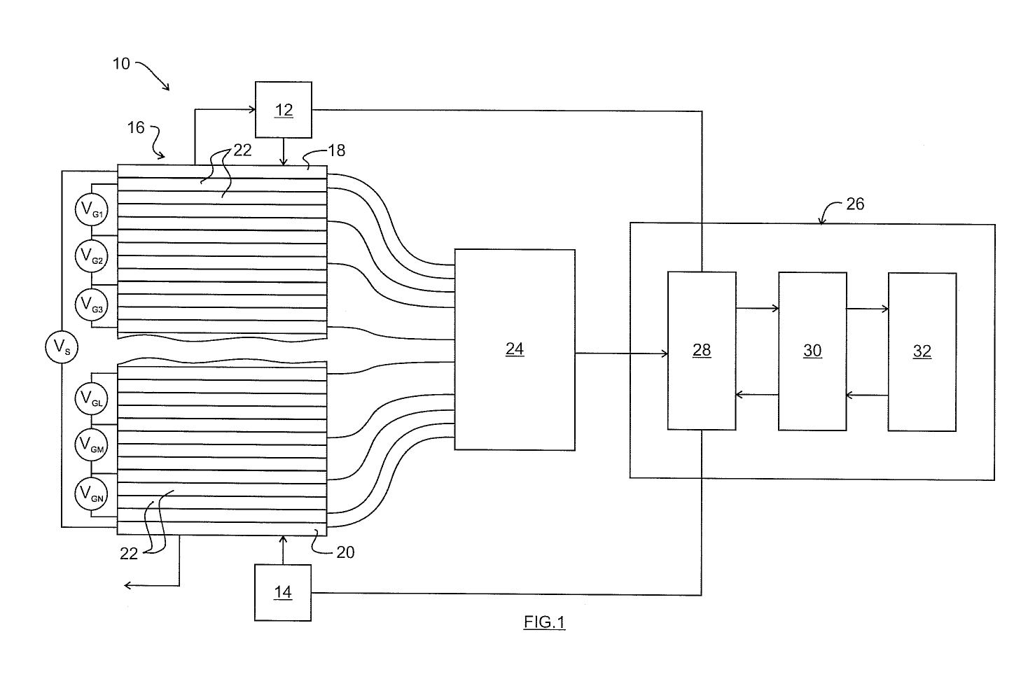

An exemplary operating environment is illustrated in FIG. 1, and may be used to implement one or more presently disclosed methods of estimated minimum voltage of fuel cells. The methods may be carried out using any suitable system and, more specifically, may be carried out in conjunction with a fuel cell system such as system 10. The following system description simply provides a brief overview of one exemplary fuel cell system, but other systems and components not shown here could also support the presently disclosed method.

In general, the fuel cell system 10 may include a fuel source 12, an oxidant source 14, and a fuel cell stack 16 coupled to the fuel and oxidant sources 12, 14.

The fuel source 12 may be a source of hydrogen, and the oxidant source 14 may be a source of oxygen such as oxygen in air. The sources 12, 14 may include any suitable storage tanks, pumps, compressors, conduit, or any other suitable components and/or devices.

The stack 16 may include end plates 18, 20 and a plurality of individual fuel cells 22 between the end plates 18, 20 to produce electrical power from a reaction of fuel and oxidant received from the fuel and oxidant sources 12, 14. The fuel cells 22 may be clustered into a plurality of fuel cell groups G₁ through G_{N}. Any suitable quantity of individual fuel cells may be provided in the groups G₁ through G_{N}.

The fuel cell system 10 may also include a voltage monitoring device 24 coupled to the stack 16 to monitor voltages of one or more of the groups and/or stack voltage exemplified by the symbol V_{S}. In one illustrative embodiment, the device 24 may be a cell voltage monitor (CVM). In another exemplary embodiment, the device 24 may be a portion of a fuel cell controller.

The system 10 may further include a controller 26 that may include, for example, an electrical circuit, an electronic circuit or chip, and/or a computing device. In the computing device embodiment, the controller 26 generally may include one or more interfaces 28, processors 30, and memory devices 32 to control operation of the system 10. In general, the controller 26 may receive and process input at least from the voltage monitoring device 24 in light of stored instructions and/or data, and transmit output signals at least to the fuel and oxidant sources 12, 14, for example, to increase or decrease output of the stack 16.

The processor(s) 30 may execute instructions that provide at least some of the functionality for the system 10. As used herein, the term instructions may include, for example, control logic, computer software and/or firmware, programmable instructions, or other suitable instructions. The processor(s) 30 may include, for example, one or more microprocessors, microcontrollers, application specific integrated circuits, and/or any other suitable type of processing device(s).

The memory device(s) 32 may be configured to provide storage for data received by or loaded to the system 10, and/or for processor-executable instructions. The data and/or instructions may be stored, for example, as look-up tables, formulas, algorithms, maps, models, and/or any other suitable format. The memory device(s) 32 may include, for example, RAM, ROM, EPROM, and/or any other suitable type of storage device(s).

The interface(s) 28 may include, for example, analog/digital or digital/analog converters, signal conditioners, amplifiers, filters, other electronic devices or software modules, and/or any other suitable interface(s). The interface(s) 28 may conform to, for example, RS-232, parallel, small computer system interface, universal serial bus, CAN, MOST, LIN, FlexRay, and/or any other suitable protocol(s). The interface(s) 28 may include circuits, software, firmware, or any other device to assist or enable the controller 26 in communicating with other devices.

Finally, although not shown, the system 10 may also include various conduit, valves, pumps, compressors, coolant sources, temperature sensors, and any other suitable components and/or devices. Those of ordinary skill in the art are familiar with the general structure and function of such elements of fuel cell systems such that a more complete description is not necessary here.

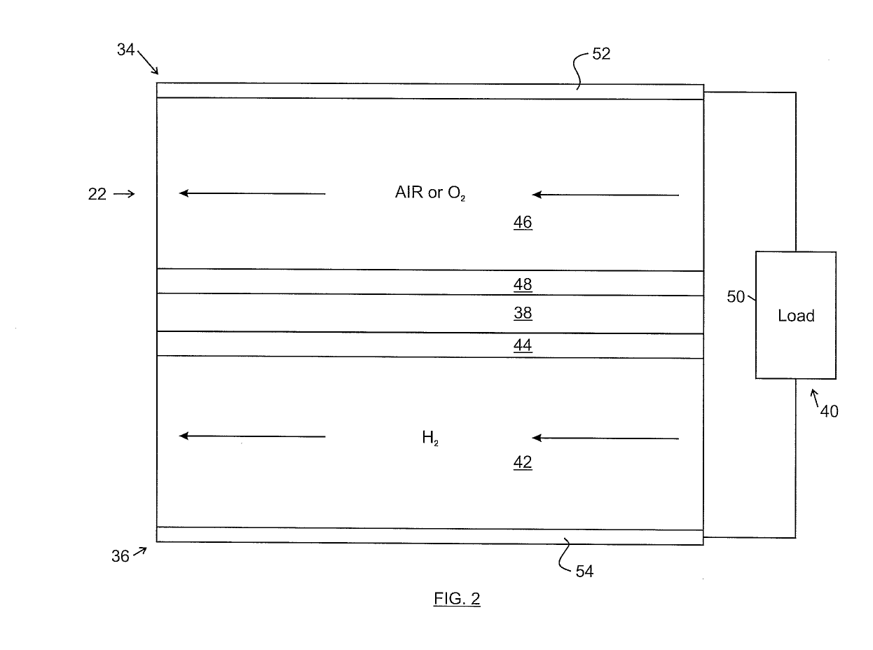

As shown in FIG. 2, an exemplary one of the fuel cells 22 may include a cathode side 34, an anode side 36, an electrolyte portion 38 sandwiched between the cathode and anode sides 34, 36, and an electrical circuit 40 across the cathode and anode sides 34, 36. Pressurized hydrogen is supplied to the anode side 36 and pressurized oxygen (in air) is supplied to the cathode side 34.

The anode side 36 may include an anode diffusion medium 42 and an anode catalyst 44 that splits the hydrogen into electrons and protons. Excess hydrogen flows away from the anode side 36 and can be recycled through the stack 16 or back to the fuel source 12 (FIG. 1). Because the electrolyte portion is an H⁺ ion conductor, the protons migrate from the anode side 36, through the electrolyte portion 38, to the cathode side 34. But because the electrolyte portion 38 is also an electrical insulator, it forces the electrons to flow through the electrical circuit 40 to do useful work en route to the cathode side 34 of the fuel cell 22.

The cathode side 34 may include a cathode diffusion medium 46 and a cathode catalyst 48 that electro-catalyzes the pressurized oxygen (in air) for combination with the protons flowing through the electrolyte portion 38 from the anode side 36 and with the electrons flowing through the electrical circuit 40, thereby yielding water as a byproduct of the reaction.

An electrical load 50 may be connected in the circuit 40 across conductive plates, which may include a cathode plate 52 on the cathode side 34 and an anode plate 54 on the anode side 36. The plates 52, 54 may be bipolar plates if they are adjacent to another fuel cell (not shown), or may be the end plates 18, 20 if they are at the ends of the fuel cell stack 16 (FIG. 1).

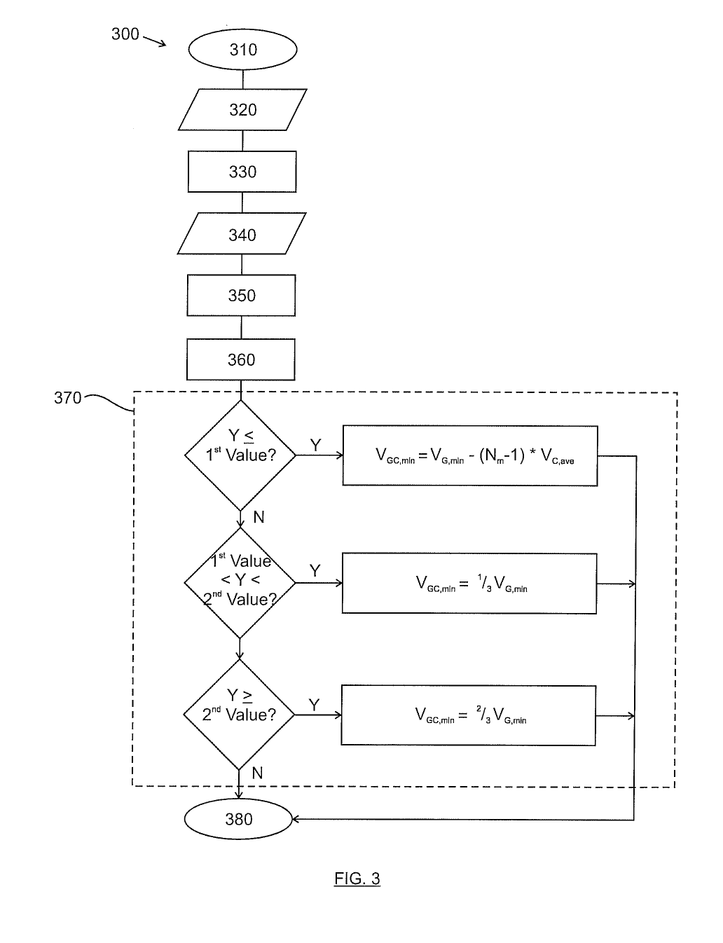

Another embodiment may include a method of estimating minimum voltage of fuel cells, that may be at least partially carried out as one or more computer programs within the operating environment of the system 10 described above. Those skilled in the art will also recognize that a method according to any number of embodiments may be carried out using other fuel cell systems within other operating environments. Referring now to FIG. 3, an exemplary method 300 is illustrated in flow chart form. As the description of the method 300 progresses, reference will be made to the exemplary system 10 of FIG. 1.

At step 310, the method may be initiated in any suitable manner, for example, at startup of a fuel cell stack.

At step 320, stack voltage of a fuel cell stack may be measured. For example, the voltage monitoring device 24 may be used as a means to measure the stack voltage (ν_{S}) of stack 16.

At step 330, average cell voltage for a fuel cell stack may be calculated. For example, the controller 26 may be used as a means to divide the measured stack voltage by the quantity of individual fuel cells 22 in the stack 16 to yield the average cell voltage (ν_{C,ave}).

At step 340, one or more group voltages of a plurality of groups of fuel cells of a fuel cell stack may be measured. For example, the voltage monitoring device 24 may be used as a means to measure the voltages of one or more of the fuel cell groups G₁ through G_{N}.

At step 350, a group of a plurality of groups of fuel cells may be identified as having a minimum group voltage (ν_{G,min}), which is lower than measured group voltages of a remainder of the plurality of groups. For example, the controller 26 may be used as a means to compare all measured group voltages of the plurality of groups and identify the lowest thereof as the minimum group voltage (ν_{G,min}).

At step 360, a group voltage deviation (Y) may be calculated for a group identified as having a minimum group voltage (ν_{G,min}). For example, the controller 26 may be used as a means to calculate the deviation (Y) by the multiplying the quantity of fuel cells (N_{M}) of the identified group by the calculated average cell voltage from step 330 and then subtracting from that product the measured group voltage of the identified group from step 350. In other words, Y=N_{M}*ν_{C,ave}−ν_{G,min}.

At step 370, a minimum cell voltage (ν_{GC,min}) of a group identified as having a minimum group voltage (ν_{G,min}) may be calculated according to a function. For example, the controller 26 may be used as a means to calculate the minimum cell voltage (ν_{GC,min}) by the following steps of the function.

In a first step of the function, if Y is less than or equal to a value, for example, a first value, then ν_{GC,min} equals ν_{G,min} minus (N_{M}−1)*(ν_{C,ave}). The first value may be about 700 mV±100 mV. As used throughout this description, the term about includes plus or minus 15%.

In a second step of the function, according to a first embodiment, if Y is greater than the first value, then ν_{GC,min} equals ν_{G,min} multiplied by a constant. The constant may be about ⅓.

According to another embodiment of the second step, if Y is greater than or equal to the first value, then ν_{GC,min} equals ν_{G,min} plus a variable. The variable may be based on current density, and may be provided in a lookup table that may be stored in the memory 32 and executed by the processor 30 of the controller 26. For example, the input parameters to the lookup table may include Y, and current density as an indication of loss of anode potential. Below, Table 1 illustrates exemplary output variables using ranges of Y as one input and ranges of current density as another input.

TABLE 1

| | | Current Density | | |
|---|---|---|---|---|
| | C_{i,j} | j < 0.2 | 0.2 ≦ j ≦ 1 | j > 1 |
| Range of Y | Y <= 100 | 5 | 20 | 10 |
| | 100 < Y ≦ 200 | 9 | 67 | 61 |
| | 200 < Y ≦ 300 | 2 | 55 | 101 |
| | 300 < Y ≦ 400 | 0 | 93 | 97 |
| | 400 < Y ≦ 500 | −11 | 106 | 117 |

According to a further embodiment of the second step, if Y is greater than the first value but less than a second value, then ν_{GC,min} equals ν_{G,min} multiplied by a first constant, which may be the same as the aforementioned constant. The second value may be about 1400 mV.

In a third step of the function, if Y is greater than or equal to the second value, then ν_{GC,min} equals ν_{G,min} multiplied by a second constant. The second constant may be about ⅔.

The function of method step 370 may include less or more steps than those set forth herein. The number of steps of the function may be determined based on any suitable stack and/or system parameters well known to those of ordinary skill in the art such as stack health, stack water quantity, and stack temperature. Furthermore, those of ordinary skill in the art will recognize that the function may be smoothed out in any suitable manner to address any discontinuities between the steps. Also, the constants may be determined based on any suitable stack and/or system parameters well known to those of ordinary skill in the art such as average stack voltage, stack health and life, stack and/or system mode (startup, shutdown, freeze, run, standby), and humidity or temperature setpoints.

At step 380, the method may be terminated in any suitable manner, for example, at shutdown of a fuel cell stack.

The method may be performed as a computer program and the various voltages, constants, values, and any other parameters may be stored in memory as a look-up table or the like. The computer program may exist in a variety of forms both active and inactive. For example, the computer program can exist as software program(s) comprised of program instructions in source code, object code, executable code or other formats; firmware program(s); or hardware description language (HDL) files. Any of the above can be embodied on a computer readable or usable medium, which include one or more storage devices and/or signals, in compressed or uncompressed form. Exemplary computer usable storage devices include conventional computer system RAM (random access memory), ROM (read only memory), EPROM (erasable, programmable ROM), EEPROM (electrically erasable, programmable ROM), and magnetic or optical disks or tapes. It is therefore to be understood that the method may be at least partially performed by any device(s) capable of executing the above-described functions.

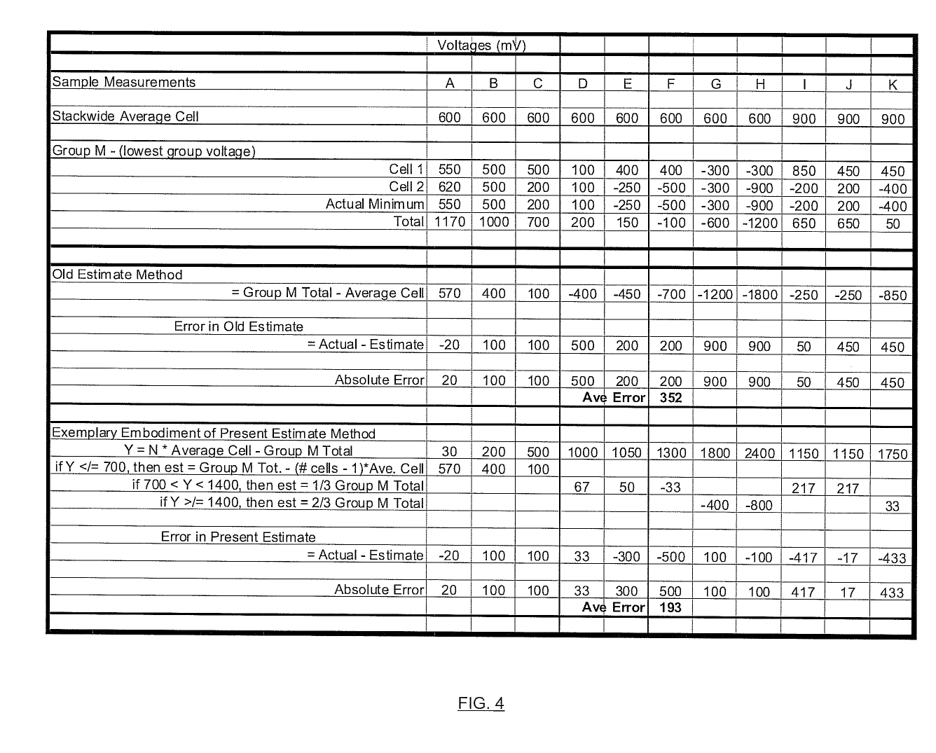

FIG. 4 illustrates a comparison of exemplary results of a prior art technique of estimating minimum cell voltage and results an exemplary embodiment of the present method of estimating minimum cell voltage. To evaluate the improvement of the minimum voltage estimation that can be obtained in accordance with the technical teachings herein, a fuel cell stack was used for testing.

The fuel stack generally included 301 individual fuel cells, and 149 fuel cell groups with two cells in each group. For test purposes, a cell voltage monitor was used to measure voltage of all individual cells, and cell group voltage was simulated by adding groups of two cell voltages together, wherein the minimum voltage of the cell groups was determined. Also, current density (current/cell area) in the stack varied from 0.1 A/CM² to 0.9 A/CM².

Several measurements A through K were taken of the same fuel cell stack, including stackwide average cell voltage, which was calculated by dividing a total stack voltage by the number of individual fuel cells in the stack. Group M represents the group of fuel cells in the stack that had the lowest voltage for the given measurement sample. Group M may or may not be the same actual group of cells from sample to sample. For purposes of verifying the results of the experiment, the voltages of individual fuel cells (Cell 1 and Cell 2) of Group M were measured. As shown, other voltages were determined or calculated including the actual minimum cell voltage in Group M, the total voltage of Group M, and the average cell voltage of Group M.

According to the old, prior art technique, estimated minimum voltage equals the Group M total voltage minus the stackwide average cell voltage. The error in the prior art technique was calculated by subtracting the estimated minimum voltage of Group M from the measured, actual minimum voltage of Group M. The absolute error values were determined, and the average error calculated from the absolute error values was determined to be 352 millivolts.

According to the exemplary embodiment of the presently disclosed method, estimated minimum voltage may be calculated by the function shown in FIG. 4. The error in the exemplary embodiment was calculated by subtracting the estimated minimum voltage of Group M from the measured, actual minimum voltage of Group M. The absolute error values were determined, and the average error calculated from the absolute error values was determined to be 193 millivolts, which, at least in this example, is almost half that of the prior art technique.

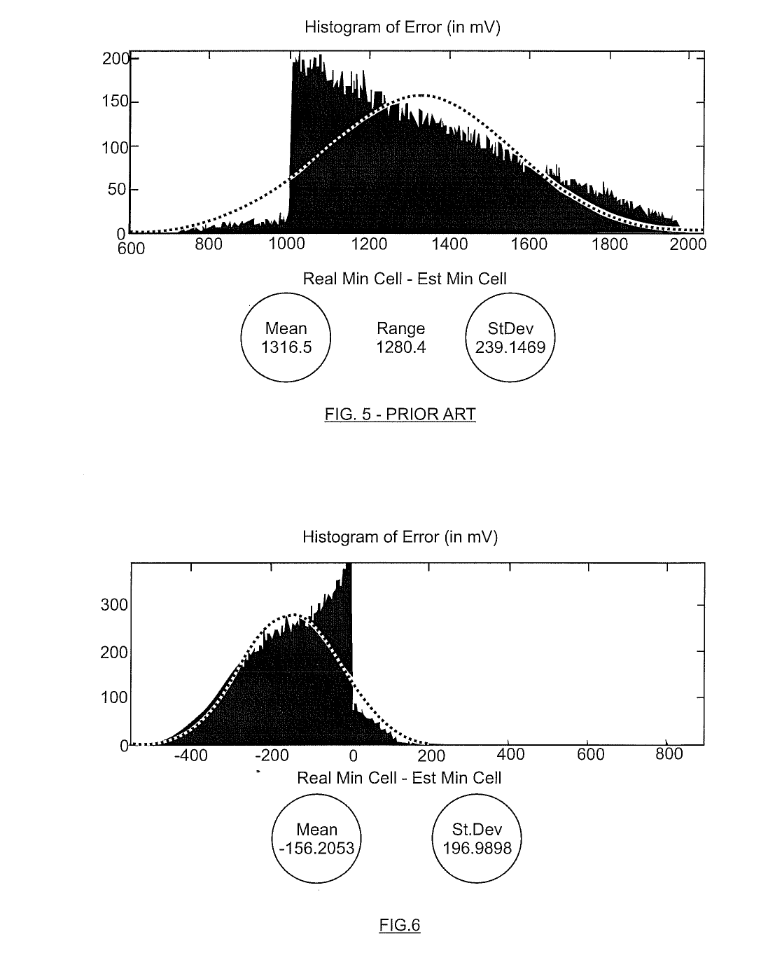

Prior art FIG. 5, and FIG. 6 demonstrate another comparison of exemplary results of a prior art technique of estimating minimum cell voltage and results an exemplary embodiment of the present method of estimating minimum cell voltage. To evaluate the improvement of the minimum voltage estimation that can be obtained in accordance with the technical teachings herein, a fuel cell stack was used for testing.

The same test setup was used as described above with respect to FIG. 4.

Prior art FIG. 5 is a histogram of error of estimated voltage in mV as a result of using another prior art technique of estimating minimum cell voltage, wherein estimated minimum voltage equals only the Group M total voltage, minus the Group M number of cells minus one, and multiplied by stackwide average cell voltage. Stated another way, ν_{GC,min}=ν_{G,min}−(N_{N}−1)*(ν_{C,ave}). The range in error was determined to be about 1280 mV, with a mean error of about 1317 mV and a standard deviation of about 239 mV.

FIG. 6 is a histogram of error of estimated voltage in mV as a result of using the exemplary embodiment of the presently disclosed method. The range in error was determined to be about 700 mV, with a mean error of about 156 millivolts and a standard deviation of about 197 mV.

The above description of embodiments is merely exemplary in nature and, thus, variations thereof are not to be regarded as a departure from the spirit and scope of the claims.

What is claimed is:

1. A method comprising:
measuring stack voltage (ν_{S}) of a fuel cell stack;
calculating average cell voltage (ν_{C,ave}) for the stack;
measuring group voltages of a plurality of groups of fuel cells of the stack;
identifying a group of the plurality of groups having a minimum group voltage (ν_{G,min}), which is lower than the measured group voltages of a remainder of the plurality of groups;
calculating a group voltage deviation (Y) for the identified group by multiplying the quantity of fuel cells (N_{M}) of the identified group by the calculated average cell voltage and then subtracting the measured group voltage of the identified group; and
estimating a minimum cell voltage (ν_{GC,min}) of the identified group according to a function wherein:
if Y is less than or equal to a value, then ν_{GC,min} equals ν_{G,min} minus (N_{M}−1)*(ν_{C,ave}); and
if Y is greater than the value, then ν_{GC,min} equals at least one of ν_{G,min} multiplied by a constant or ν_{G,min} plus a variable.

2. A method as set forth in claim 1 wherein:
if Y is greater than the value but less than a second value, then ν_{GC,min} equals ν_{G,min} multiplied by the constant; and
if Y is greater than or equal to second value, then ν_{GC,min} equals ν_{G,min} multiplied by a second constant.

3. A method as set forth in claim 1 further wherein the constant is about ⅓.

4. A method as set forth in claim 2 further wherein the second constant is about ⅔.

5. A method as set forth in claim 1 further wherein the value is about 700 mV.

6. A method as set forth in claim 2 further wherein the second value is about 1400 mV.

7. A method as set forth in claim 2 further wherein the constant is about ⅓ and the second constant is about ⅔.

8. A method as set forth in claim 7 further wherein the value is about 700 mV and the second value is about 1400 mV.

9. A method as set forth in claim 1 wherein the variable is based on current density.

10. A method as set forth in claim 9 wherein the variable is provided by a lookup table.

11. A method comprising:
identifying a group of a plurality of groups of fuel cells of a fuel cell stack having a minimum group voltage (ν_{G,min}), which is lower than any group voltage of a remainder of the plurality of groups;
calculating a group voltage deviation (Y) for the identified group by multiplying the quantity of fuel cells (N_{M}) of the identified group by an average cell voltage (ν_{C,ave}) of the fuel cell stack and then subtracting the minimum group voltage; and
estimating a minimum cell voltage (ν_{GC,min}) of the identified group according to a function including a step wherein if Y is less than or equal to a value, then ν_{GC,min} equals ν_{G,min} minus (N_{M}−1)*(ν_{C,ave}).

12. A method as set forth in claim 11 wherein the function includes a second step wherein if Y is greater than the value, then ν_{GC,min} equals ν_{G,min} multiplied by a constant.

13. A method as set forth in claim 12 wherein the second step further provides that if Y is greater than the value but less than a second value, then ν_{GC,min} equals ν_{G,min} multiplied by the constant.

14. A method as set forth in claim 13 further wherein the constant is about ⅓.

15. A method as set forth in claim 13 further wherein the value is about 700 mV.

16. A method as set forth in claim 13 wherein the function includes a third step wherein if Y is greater than or equal to second value, then ν_{GC,min} equals ν_{G,min} multiplied by a second constant.

17. A method as set forth in claim 16 further wherein the second constant is about ⅔.

18. A method as set forth in claim 16 further wherein the second value is about 1400 mV.

19. A method as set forth in claim 11 wherein the function includes a second step wherein if Y is greater than the value, then ν_{GC,min} equals ν_{G,min} plus a variable.

20. A method as set forth in claim 19 wherein the variable is based on current density.

21. A product comprising:
a fuel cell stack including a plurality of fuel cells, at least some of which are clustered into a plurality of groups;
a voltage monitoring device coupled to the fuel cell stack to measure stack voltage of the fuel cell stack and group voltages of at least some of the plurality of groups; and
a controller coupled to the voltage monitoring device to:
calculate average cell voltage (ν_{C,ave}) for the stack,
identify a group of the plurality of groups having a minimum group voltage (ν_{G,min}), which is lower than the measured group voltages of a remainder of the plurality of groups,
calculate a group voltage deviation (Y) for the identified group by multiplying the quantity of fuel cells (N_{M}) of the identified group by the calculated average cell voltage and then subtracting the measured group voltage of the identified group, and
estimate a minimum cell voltage (ν_{GC,min}) of the identified group according to a function wherein:
if Y is less than or equal to a value, then ν_{GC,min} equals ν_{G,min} minus (N_{M}−1)*(ν_{C,ave}); and
if Y is greater than the value, then ν_{GC,min} equals at least one of ν_{G,min} multiplied by a constant or ν_{G,min} plus a variable.

22. A product as set forth in claim 21 wherein, according to the function,
if Y is greater than the value but less than a second value, then ν_{GC,min} equals ν_{G,min} multiplied by the constant; and
if Y is greater than or equal to second value, then ν_{GC,min} equals ν_{G,min} multiplied by a second constant.

23. A product as set forth in claim 21 wherein the variable is based on current density.

24. A product comprising:
a means for identifying a group of a plurality of groups of fuel cells of a fuel cell stack having a minimum group voltage (ν_{G,min}), which is lower than any group voltage of a remainder of the plurality of groups;
a means for calculating a group voltage deviation (Y) for the identified group by multiplying the quantity of fuel cells (N_{M}) of the identified group by an average cell voltage (ν_{C,ave}) of the fuel cell stack and then subtracting the minimum group voltage; and
a means for estimating a minimum cell voltage (ν_{GC,min}) of the identified group according to a function including a step wherein if Y is less than or equal to a value, then ν_{GC,min} equals ν_{G,min} minus (N_{M}−1)*(ν_{C,ave}).
